(19) United States
(12) Patent Application Publication
(10) Pub. No.: US 2023/0420612 A1
(43) Pub. Date: Dec. 28, 2023

(54) MICRO LIGHT-EMITTING DEVICE, MICRO LIGHT-EMITTING DIODE, AND METHOD FOR MANUFACTURING MICRO LIGHT-EMITTING DEVICE

(71) Applicants: XIAMEN SAN'AN OPTOELECTRONICS TECHNOLOGY CO., LTD., Fujian (CN); HUAWEI DEVICE CO., LTD., Guangdong (CN)

(72) Inventors: Yenchin WANG, Tianjin (CN); Shuiqing LI, Fujian (CN); Shaohua HUANG, Fujian (CN); Minghui CHEN, Guangdong (CN); Shuang QU, Guangdong (CN)

(21) Appl. No.: 18/462,798

(22) Filed: Sep. 7, 2023

Related U.S. Application Data
(63) Continuation-in-part of application No. PCT/CN2021/080560, filed on Mar. 12, 2021.

(51) Int. Cl. H01L 33/20; H01L 33/00; H01L 33/62

(52) U.S. Cl. CPC H01L 33/20; H01L 33/0062; H01L 33/0093; H01L 33/62; H01L 2933/0016; H01L 2933/0066

(57) ABSTRACT

A micro light-emitting device includes a micro light-emitting diode, a base frame, and a bridging structure. The micro light-emitting diode includes a semiconductor epitaxial structure including a first semiconductor layer, a second semiconductor layer, an active layer, a first mesa surface, a second mesa surface, and a connecting wall, a first contact electrode, a second contact electrode, a first bonding electrode, and a second bonding electrode. The connecting wall cooperates with the first mesa surface to form a first included angle that ranges from 105° to 165°. A micro light-emitting diode and a method of manufacturing a micro light-emitting device are also provided.

### CROSS-REFERENCE TO RELATED APPLICATION

This application is a continuation-in-part (CIP) of International Application No. PCT/CN2021/080560, filed on Mar. 12, 2021, which is incorporated herein by reference in its entirety.

### FIELD

The disclosure relates to a semiconductor device, and more particularly to a micro light-emitting device, a micro light-emitting diode, and a method for manufacturing a micro light-emitting device.

### BACKGROUND

A micro light-emitting diode (mLED) has advantages of being self-emitting, high efficiency, low power consumption, high luminous intensity, high stability, ultra-high resolution and color saturation, fast response rate, and long lifespan, and is widely applied in display, optical communication, indoor positioning, and biological and medical fields. mLED is expected to further expand its application to wearable/implantable devices, augmented display/virtual reality, in-vehicle display, ultra-large display and optical communication/optical interconnection, medical detection, intelligent vehicle lights, spatial imaging, and many other fields. It has a clear and considerable market prospect.

There are still many technical challenges to be overcome for the mLED, and one of key challenges is improving yield of mass transfer of the mLED.

Referring to FIG. 1, a conventional micro light-emitting device typically includes a micro light-emitting diode, a base frame 250 that includes a substrate 220 and a bonding layer 210 and that is formed with an indented receiving space 230, and a bridging structure 240. The micro light-emitting diode includes a first contact electrode 204, a second contact electrode 205, a first bonding electrode 207, a second bonding electrode 208, and a semiconductor epitaxial structure. The semiconductor epitaxial structure includes a first semiconductor layer 201, a second semiconductor layer 203, and an active layer 202 disposed between the first semiconductor layer 201 and the second semiconductor layer 203, and has a first mesa surface (S11), a second mesa surface (S12), and a connecting wall (W11) that interconnects the first mesa surface (S11) and the second mesa surface (S12). The difference in height between the first and second mesa surfaces (S11, S12) is relatively large, and an included angle between the first mesa surface (S11) and the connecting wall (W11) is close to 90°. Thus, when the first mesa surface (S11), the second mesa surface (S12), and the connecting wall (W11) are covered by a sacrificial layer 209, the sacrificial layer 209 is likely to break. In addition, during bonding of the micro light-emitting diode to the substrate 220, material of the bonding layer 210 is likely to diffuse into the broken sacrificial layer 209 and contacts the micro light-emitting diode. An abnormal transfer of the micro light-emitting diode may thus occur, thereby affecting yield of final products.

### SUMMARY

Therefore, an object of the disclosure is to provide a micro light-emitting device, a micro light-emitting diode, and a method of manufacturing a micro light-emitting device that can alleviate at least one of the drawbacks of the prior art.

According to a first aspect of the disclosure, a micro light-emitting device includes a micro light-emitting diode, a base frame, and a bridging structure.

The micro light-emitting diode includes a semiconductor epitaxial structure, a first contact electrode, a second contact electrode, a first bonding electrode, and a second bonding electrode.

The semiconductor epitaxial structure includes a first semiconductor layer, a second semiconductor layer, and an active layer disposed between the first semiconductor layer and the second semiconductor layer. The semiconductor epitaxial structure has a first mesa surface defined by the first semiconductor layer that is exposed from a recess of the semiconductor epitaxial structure, a second mesa surface defined by the second semiconductor layer, and a connecting wall disposed between and interconnecting the first mesa surface and the second mesa surface. The connecting wall cooperates with the first mesa surface to form a first included angle that ranges from 105° to 165°.

The first contact electrode is disposed on the first mesa surface and electrically connected to the first semiconductor layer. The second contact electrode is disposed on the second mesa surface and electrically connected to the second semiconductor layer. The first bonding electrode is disposed on and electrically connected to the first contact electrode, and the second bonding electrode is disposed on and electrically connected to the second contact electrode.

The base frame is disposed on and supports the micro light-emitting diode. The bridging structure interconnects the micro light-emitting diode and the base frame, and a periphery of the micro light-emitting diode is disposed on the bridging structure.

According to a second aspect of the disclosure, a micro light-emitting diode includes elements and structures the same as the aforementioned micro light-emitting diode.

According to a third aspect of the disclosure, a method for manufacturing a micro light-emitting device includes steps of:
forming a semiconductor epitaxial structure on a growth substrate, the semiconductor epitaxial structure including a first semiconductor layer, a second semiconductor layer, and an active layer disposed between the first semiconductor layer and the second semiconductor layer;
removing a portion of the semiconductor epitaxial structure to expose the first semiconductor layer and to form a first mesa surface, a second mesa surface, and a connecting wall, the first mesa surface being defined by the exposed first semiconductor layer, the second mesa surface being defined by the second semiconductor layer, the connecting wall being disposed between and interconnecting the first mesa surface and the second mesa surface, and cooperating with the first mesa surface to form a first included angle (θ1), where 105°≤θ1≤165°;
forming a first contact electrode and a second contact electrode on the first mesa surface (S1) and the second mesa surface (S2), respectively, and forming a first bonding electrode and a second bonding electrode on the first contact electrode and the second contact electrode, respectively, so as to obtain a micro light-emitting diode;
forming a sacrificial layer on the micro light-emitting diode;
providing a base frame having an indented receiving space;
bonding the micro light-emitting diode to the base frame with the sacrificial layer facing the base frame so that the micro light-emitting diode is disposed in the indented receiving space of the base frame;
removing the growth substrate; and
separating the micro light-emitting diode from the base frame by transfer printing and transferring the micro light-emitting diode onto a packaging substrate.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a conventional micro light-emitting device.

FIG. 2 is a schematic view illustrating an embodiment of a micro light-emitting device according to the disclosure.

FIGS. 3 to 13 are schematic diagrams illustrating a method for manufacturing a micro light-emitting device according to the disclosure.

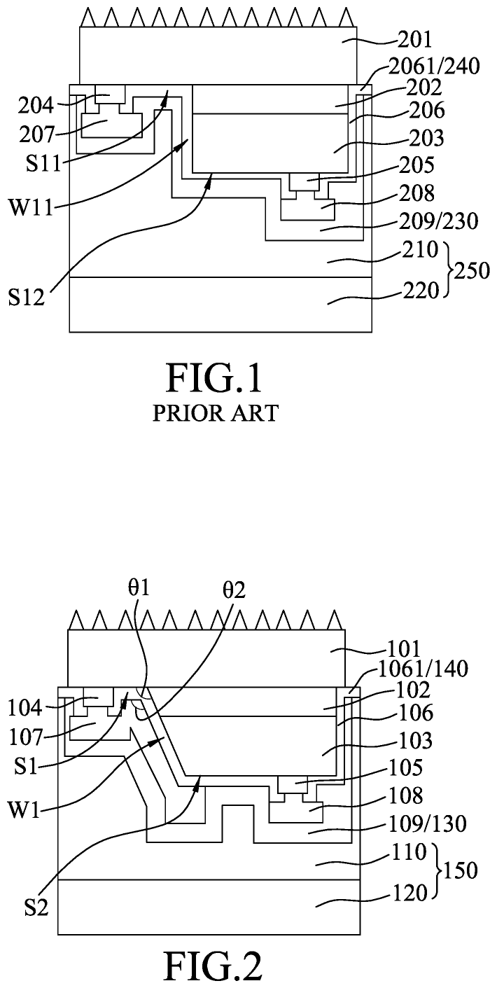

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Referring to FIG. 2, the present disclosure provides a micro light-emitting device including at least one micro light-emitting diode, which has a flip-chip structure. Since a size of a micro light-emitting diode is small, a manufacturing method thereof differs from one of a conventional non-micro light-emitting diode. In the present disclosure, the micro light-emitting diode primarily refers to one having a size (i.e., in length, width or height) ranging from greater than or equal to 2 μm to smaller than 5 μm, from greater than or equal to 5 μm to smaller than 10 μm, from greater than or equal to 10 μm to smaller than 20 μm, from greater than or equal to 20 μm to smaller than 50 μm, or from greater than or equal to 50 μm to smaller than or equal to 100 μm.

The micro light-emitting diode includes a semiconductor epitaxial structure, a first contact electrode 104, a second contact electrode 105, a first bonding electrode 107 and a second bonding electrode 108. The semiconductor epitaxial structure includes a first semiconductor layer 101, a second semiconductor layer 103, and an active layer 102 disposed between the first semiconductor layer 101 and the second semiconductor layer 103. The semiconductor epitaxial structure has a first mesa surface (S1) defined by a the first semiconductor layer 101 that is exposed from a recess of the semiconductor epitaxial structure, a second mesa surface (S2) defined by the second semiconductor layer 103, and a connecting wall (W1) disposed between and interconnecting the first mesa surface (S1) and the second mesa surface (S2). The first contact electrode 104 is disposed on the first mesa surface (S1) and electrically connected to the first semiconductor layer 101. The second contact electrode 105 is disposed on the second mesa surface (S2) and electrically connected to the second semiconductor layer 103. The first bonding electrode 107 is disposed on and electrically connected to the first contact electrode 104. The second bonding electrode 108 is disposed on and electrically connected to the second contact electrode 105.

The first semiconductor layer 101 may be made of a group III-V or group II-VI compound semiconductor material, and may be doped with a first dopant. The first semiconductor layer 101 may be made of a semiconductor material having a composition that is represented by InₓAl_{y1}Ga_{1-x1-y1}N (0≤x1≤1, 0≤y1≤1, 0≤x1+y1≤1), e.g., GaN, AlGaN, InGaN, InAlGaN, etc., or a material selected from AlGaAs, GaP, GaAs, GaAsP, and AlGaInP. In addition, the first dopant may be an n-type dopant, such as Si, Ge, Sn, Se, and Te. When the first dopant is an n-type dopant, the first semiconductor layer 101 doped with the first dopant is an n-type semiconductor layer. The first dopant may be a p-type dopant, such as Mg, Zn, Ca, Sr, and Ba. The first semiconductor layer 101 doped with the p-type dopant is a p-type semiconductor layer. A surface of the first semiconductor layer 101 away from the active layer 102 is a light-emitting surface. To improve light extraction efficiency of the micro light-emitting diode, the light-emitting surface of the first semiconductor layer 101 may be roughened to form a roughened structure. In some embodiments, the light-emitting surface of the first semiconductor layer 101 may not be roughened.

The active layer 102 is disposed between the first semiconductor layer 101 and the second semiconductor layer 103. The active layer 102 is a region for electrons and holes to recombine for light emitting. Depending on a wavelength of light emitted by the active layer 102, materials for the active layer 102 may vary. The active layer 102 may have a single quantum well structure or a multiple quantum well structure. The active layer 102 may include well layer(s) and barrier layer(s), and a bandgap of the barrier layer is greater than that of the well layer. By adjusting a composition of the semiconductor material of the active layer 102, the active layer 102 may emit a pre-determined wavelength of light.

The second semiconductor layer 103 is disposed on the active layer 102, and may be made of a group III-V or group II-VI compound semiconductor material. The second semiconductor layer 103 may be doped with a second dopant. The second semiconductor layer 103 may be made of a semiconductor material having a composition that is represented by Inₓ₂Al_{y2}Ga_{1-x2-y2}N (0≤x2≤1, 0≤y2≤1, 0≤x2+y2≤1), or a material selected from AlGaAs, GaP, GaAs, GaAsP, and AlGaInP. When the second dopant is a p-type dopant, such as Mg, Zn, Ca, Sr, and Ba, the second semiconductor layer 103 doped with the second dopant is a p-type semiconductor layer. The second dopant may be an n-type dopant, such as Si, Ge, Sn, Se, and Te. When the second semiconductor layer 103 doped with the n-type dopant, the second semiconductor layer 103 is an n-type semiconductor layer. When the first semiconductor layer 101 is an n-type semiconductor layer, the second semiconductor layer 103 is a p-type semiconductor layer. Conversely, when the first semiconductor layer 101 is a p-type semiconductor layer, the second semiconductor layer 103 is an n-type semiconductor layer.

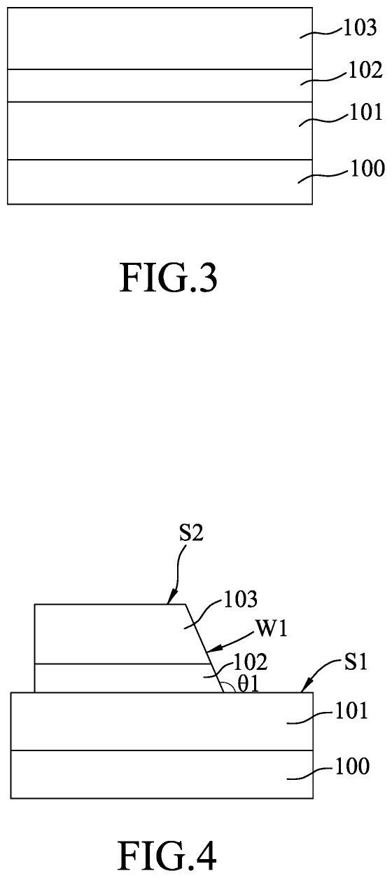

The semiconductor epitaxial structure may also include other layers, such as a current spreading layer, a window layer, or an ohmic contact layer, etc. Each of the layers may have a different doping concentration or component content. The semiconductor epitaxial structure may be formed on a growth substrate 100 (see FIG. 3) by using methods such as physical vapor deposition (PVD), chemical vapor deposition (CVD), epitaxy growth technology, atomic layer deposition (ALD), etc. In this embodiment, the semiconductor epitaxial structure is made of AlGaInP-based material, and emits red light.

To increase reliability of the micro light-emitting diode, the micro light-emitting diode further includes an insulation layer 106 that covers the connecting wall (W1), the first mesa surface (S1), and the second mesa surface (S2). The insulation layer 106 may be made of SiNx (e.g., Si₃N₄) or SiO₂, and has a thickness no smaller than 1 μm.

The first contact electrode 104 and the second contact electrode 105 may be made of, for example, Au or AuZn. In certain embodiments, the first contact electrode 104 has a multi-layered structure which includes Au/Ni/Au/GeAu/Ni/Au, and the second contact electrode 105 has a multi-layered structure which includes Au/AuZn/Au. The first bonding electrode 107 and the second bonding electrode 108 may be made of one of Au, Ag, Al, Pt, Ti, Ni, Cr, or combinations thereof. In some embodiments, the first bonding electrode 107 and the second bonding electrode 108 may be made of a reflective metal such as Au or Al, which may increase the light extraction efficiency and luminous intensity of the micro light-emitting diode. Each of the first bonding electrode 107 and the second bonding electrode 108 has a thickness ranging from 0.5 μm to 3 μm.

The micro light-emitting device further includes a bridging structure 140 and a base frame 150 supporting the micro light-emitting diode. The base frame 150 is disposed on the micro light-emitting diode, and has an indented receiving space 130 for disposing the micro light-emitting diode. The bridging structure 140 is connected to the micro light-emitting diode and the base frame 150. The base frame 150 includes a substrate 120 and a bonding layer 110 disposed on the substrate 120. The bonding layer 110 may be made of a benzocyclobutene (BCB) adhesive, silicone, an ultraviolet (UV) adhesive or resin. The resin may be gamma-butyrolactone, 1-methoxy-2-propyl acetate, polyamic acid, or combinations thereof, or a mixture of benzocyclobutene or bisphenol fluorene epoxy acrylate additives with propylene glycol monomethyl ether acetate. The bridging structure 140 may be made of a dielectric material, a metal material, or a semiconductor material. In certain embodiments, the bridging structure 140 is integrally formed with the insulation layer 106, and is connected to and extends from the insulation layer 106 away from the semiconductor epitaxial structure. The bridging structure 140 may also be seen as a horizontal portion 1061 of the insulation layer 106. The bridging structure 140 is disposed on the bonding layer 110, connects the bonding layer 110 to the micro light-emitting diode, and interconnects the micro light-emitting diode and the base frame 150 with a periphery of the micro light-emitting diode being disposed on the bridging structure 140.

The micro light-emitting diode is separated from the base frame 150 by transfer printing. In some cases, the micro light-emitting device includes a sacrificial layer 109 that is disposed in the indented receiving space 130 and between the micro light-emitting diode and the base frame 150. In certain circumstances, the sacrificial layer 109 has a higher removal efficiency than that of the micro light-emitting diode and may be removed by chemical degradation or physical degradation, such as UV decomposition, etching, or pyrolysis. Examples of a material for the sacrificial layer 109 include polydimethylsiloxane (PDMS), silicone, a pyrolysis adhesive, and a UV adhesive. A part of the sacrificial layer 109 covering the connecting wall (W1) has a thickness no smaller than 1 μm measured from the connecting wall (W1).

In the prior art, the first mesa surface (S1) and the second mesa surface (S2) have a difference in height, and the connecting wall (W1) is substantially vertical. When the sacrificial layer 109 covers the first mesa surface (S1), the second mesa surface (S2), and the connecting wall (W1), the sacrificial layer 109 may easily break. Then, during bonding of the micro light-emitting diode to the substrate 120, material of the bonding layer 110 may easily diffuse into the sacrificial layer 109 and contacts the micro light-emitting diode, thereby causing an abnormal transfer of the micro light-emitting diode and affecting yield of the product.

To resolve the above-mentioned problem, in the present disclosure, the connecting wall (W1), which is tilted, cooperates with the first mesa surface (S1) to form a first included angle (θ1), where 105°≤θ1≤165°. In some embodiments, 120°≤θ1≤150°. A part of the insulation layer 106 that covers the connecting wall (W1) cooperates with a part of the insulation layer 106 that covers the first mesa surface (S1) to form a second included angle (θ2), where 105°≤θ2≤165°. In some embodiments, 120°≤θ2≤150°. The sacrificial layer 109 may then better cover the connecting wall (W1), and breakage of the sacrificial layer 109 may be avoided, so that the material of the bonding layer 110 may not diffuse into the sacrificial layer 109 and contacts the micro light-emitting diode, so the abnormal transfer of the micro light-emitting diode may be avoided.

In some embodiments, the first bonding electrode 107 extends onto the second mesa surface (S2) and is flush with the second bonding electrode 108. By virtue of the first bonding electrode 107 covering the connecting wall (W1), and connecting to the second mesa surface (S2), the sacrificial layer 109 may better cover the connecting wall (W1) without breakage, thereby improving transfer yield of the micro light-emitting diode. Meanwhile, the first bonding electrode 107 is flush with the second bonding electrode 108, which is conducive to subsequent packaging and improves packaging yield.

The present disclosure also provides a micro light-emitting diode as described in the aforesaid embodiment of the light-emitting device.

FIGS. 3 to 13 are schematic diagrams illustrating a method for manufacturing a micro light-emitting device according to the disclosure. Detailed descriptions are given below in connection with the schematic diagrams. First, referring to FIG. 3, an epitaxial structure is formed on the growth substrate 100 (e.g., a GaAs substrate) by metal-organic chemical vapor deposition (MOCVD), and includes the first semiconductor layer 101, the second semiconductor layer 103, and the active layer 102 disposed between the first semiconductor layer 101 and the second semiconductor layer 103. The semiconductor epitaxial structure may be made of an AlGaInP-based material, and the active layer 102 emits red light.

Then, referring to FIG. 4, a portion of the semiconductor epitaxial structure is removed by a dry etching process to expose the first semiconductor layer 101 and to form the first mesa surface (S1), the second mesa surface (S2) and the connecting wall (W1). The first mesa surface (S1) is defined by the exposed first semiconductor layer 101. The second mesa surface (S2) is defined by the second semiconductor layer 103. The connecting wall (W1) is disposed between and interconnects the first mesa surface (S1) and the second mesa surface (S2). The connecting wall (W1) cooperates with the first mesa surface (S1) to form the first included angle (θ1), where 105°≤θ1≤165°. In some embodiments, 120°≤θ1≤150°. The connecting wall (W1) with the specific first included angle (θ1) may be formed by adjusting a flow rate and power of gas in the dry etching process, or by using a photoresist having a pattern corresponding to that of the tilted connecting wall (W1).

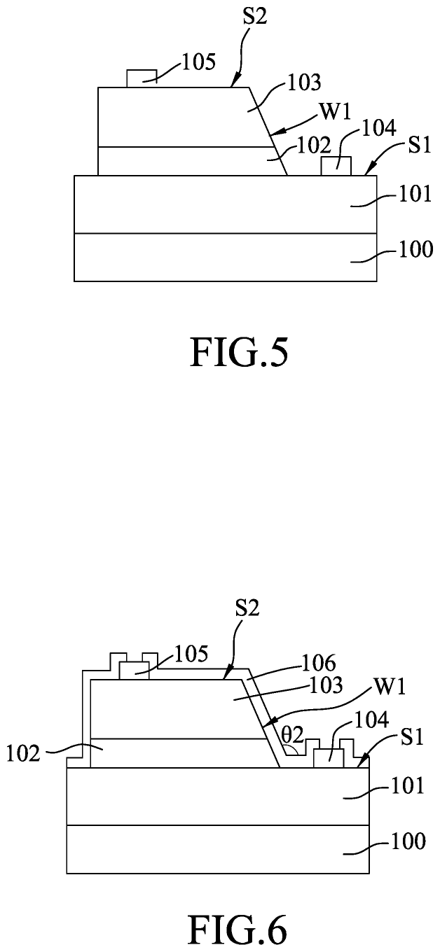

Next, referring to FIG. 5, the first contact electrode 104 and the second contact electrode 105 are formed on the first mesa surface (S1) and the second mesa surface (S2), respectively, and the first contact electrode 104 and the second contact electrode 105 form ohmic contacts with the first semiconductor layer 101 and the second semiconductor layer 103, respectively. The first contact electrode 104 may have a multi-layered structure which includes Au/Ni/Au/GeAu/Ni/Au, and the second contact electrode 105 may have a multi-layered structure which includes Au/AuZn/Au. In this step, the first contact electrode 104 and the second contact electrode 105 may be fused with the semiconductor epitaxial structure to form good ohmic contacts.

Subsequently, referring to FIG. 6, the insulation layer 106 is formed to cover the connecting wall (W1), the first mesa surface (S1), and the second mesa surface (S2). The insulation layer 106 is etched to form openings on the first contact electrode 104 and the second contact electrode 105. In certain embodiments, the insulation layer 106 is made of SiNx (e.g., Si₃N₄) or SiO₂ and has a thickness no smaller than 1 μm.

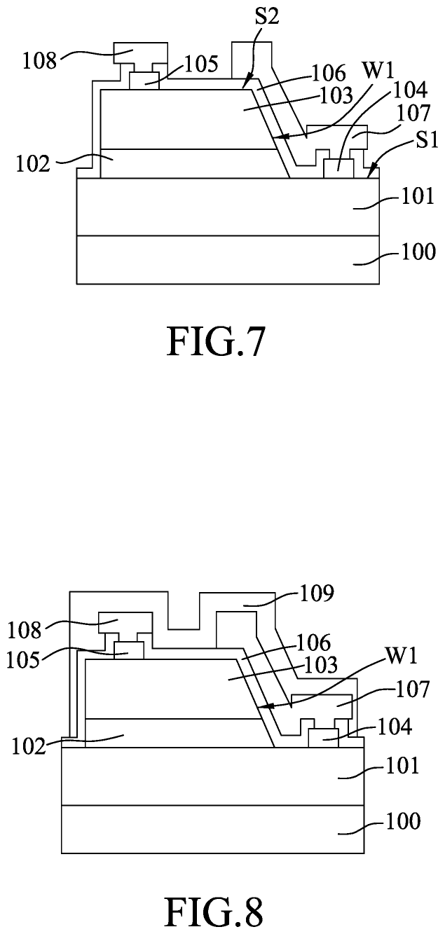

Then, referring to FIG. 7, the first bonding electrode 107 and the second bonding electrode 108 are formed on the first contact electrode 104 and the second contact electrode 105, respectively. The first bonding electrode 107 and the second bonding electrode 108 are respectively and electrically connected to the first contact electrode 104 and the second contact electrode 105 through the openings in the insulation layer 106, so as to obtain the micro light-emitting diode. The first bonding electrode 107 covers the connecting wall (W1), extends onto the second mesa surface (S2), and is flush with the second bonding electrode 108. Next, referring to FIG. 8, the sacrificial layer 109 is formed on the micro light-emitting diode. In certain embodiments, the sacrificial layer 109 covering the connecting wall (W1) is no smaller than 1 μm in thickness measured from the connecting wall (W1), and is made of an oxide material, a nitride material, or a material that may be selectively removed during etching relative to other layers.

Then, the base frame (150) having the indented receiving space 130 is provided on the sacrificial layer 109 to support the micro light-emitting diode.

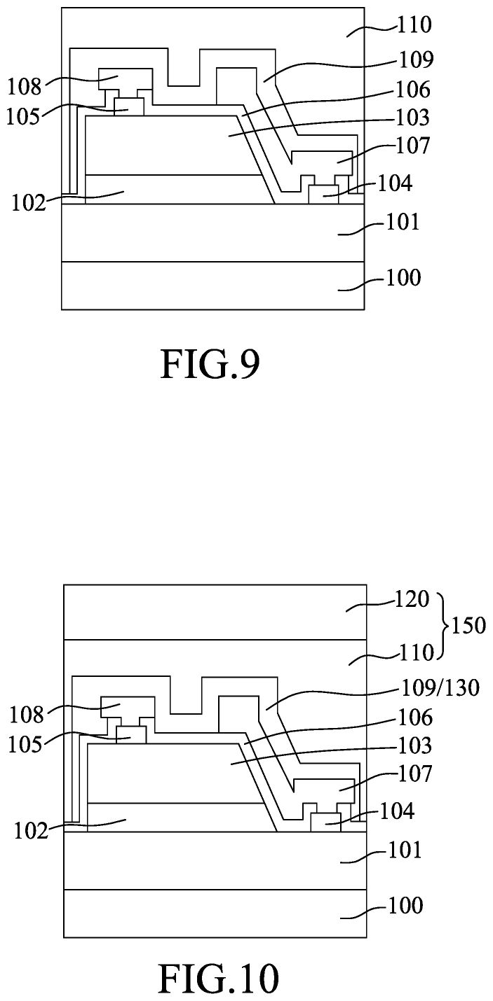

To be specific, referring to FIG. 9, a bonding adhesive (e.g., a BCB adhesive) is formed on the sacrificial layer 109 so as to form the bonding layer 110. Then, referring to FIG. 10, the micro light-emitting diode along with the sacrificial layer 109 is bonded to the substrate 120 by the bonding layer 110. The micro light-emitting diode is bonded to the base frame 150 with the sacrificial layer 109 facing the base frame 150 so that the micro light-emitting diode is disposed in the indented receiving space 130 of the base frame 150.

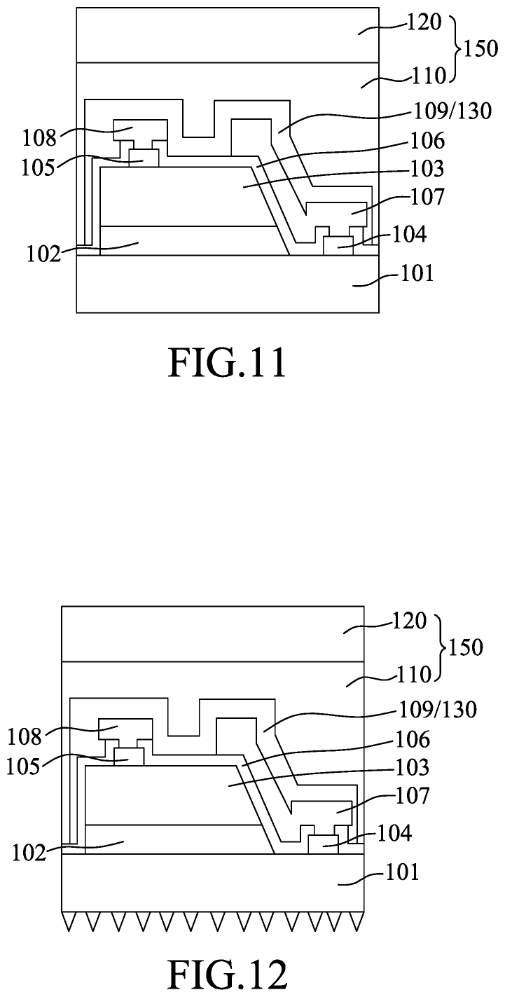

Then, referring to FIGS. 10 and 11, the growth substrate 100 is removed. In certain embodiment, a portion of the semiconductor epitaxial structure may be removed.

Next, referring to FIG. 12, the surface of the first semiconductor layer 101 away from the substrate 120 is roughened to increase the light extraction efficiency of the micro light-emitting diode.

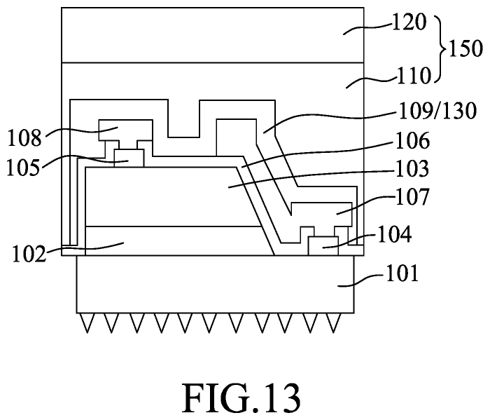

Then, referring to FIG. 13, in certain embodiments, edges of the first semiconductor layer 101 are removed by e.g., etching, and etching procedure is stopped at the insulation layer 106. Individual chiplets are thus formed for facilitating subsequent separation of the chiplets when the method is formed to have a plurality of light-emitting diodes on the substrate 100 (the light-emitting diodes are formed into the chiplets through the aforesaid steps).

Next, the micro light-emitting diode is separated from the base frame 150 by a transfer printing and is transferred onto a packaging substrate (not shown in the figure).

The present disclosure may improve the transfer yield of the micro light-emitting diode by designing the connecting wall (W1) to have the first included angle (θ1). By having the first bonding electrode 107 extending onto the second mesa surface (S2), the sacrificial layer 109 may better cover the slanted connecting wall (W1), thereby reducing the difference in height between the first mesa surface (S1) and the second mesa surface (S2) and resolving the breaking of the sacrificial layer 109 during the bonding process. In this way, the material of the bonding layer 110 may not diffuse into the sacrificial layer 109 and contacts the micro light-emitting diode, thereby avoiding the abnormal transfer of the micro light-emitting diode. The transfer yield of the micro light-emitting diode is then improved. In addition, each of the first bonding electrode 107 and the second bonding electrode 108 may be made of a reflective metal material to improve reflection of light, thereby enhancing the luminous intensity of the micro light-emitting diode and improving wall-plug efficiency (WPE). The first bonding electrode 107 and the second bonding electrode 108 of the micro light-emitting diode are flush with each other, which is conducive to the subsequent packaging, and improves the packaging yield.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A micro light-emitting device, comprising:
a micro light-emitting diode that includes
a semiconductor epitaxial structure including a first semiconductor layer, a second semiconductor layer, and an active layer disposed between said first semiconductor layer and said second semiconductor layer, said semiconductor epitaxial structure having a first mesa surface defined by said first semiconductor layer that is exposed from a recess of said semiconductor epitaxial structure, a second mesa surface defined by said second semiconductor layer, and a connecting wall disposed between and interconnecting said first mesa surface and said second mesa surface,
a first contact electrode disposed on said first mesa surface and electrically connected to said first semiconductor layer,
a second contact electrode disposed on said second mesa surface and electrically connected to said second semiconductor layer,
a first bonding electrode disposed on and electrically connected to said first contact electrode, and
a second bonding electrode disposed on and electrically connected to said second contact electrode;
a base frame that is disposed on and supports said micro light-emitting diode; and
a bridging structure that interconnects said micro light-emitting diode and said base frame, a periphery of said micro light-emitting diode being disposed on said bridging structure,
wherein said connecting wall cooperates with said first mesa surface to form a first included angle, where 105°≤θ1≤165°.

2. The micro light-emitting device as claimed in claim 1, wherein said first included angle ranges from 120° to 150°.

3. The micro light-emitting device as claimed in claim 1, wherein said first bonding electrode extends onto said second mesa surface and is flush with said second bonding electrode.

4. The micro light-emitting device as claimed in claim 1, wherein each of said first bonding electrode and said second bonding electrode is made of one of Au, Ag, Al, Pt, Ti, Ni, Cr, or combinations thereof.

5. The micro light-emitting device as claimed in claim 1, wherein each of said first bonding electrode and said second bonding electrode has a thickness ranging from 0.5 μm to 3 μm.

6. The micro light-emitting device as claimed in claim 1, wherein said micro light-emitting diode further includes an insulation layer that covers said connecting wall, said first mesa surface, and said second mesa surface, a part of said insulation layer that covers said connecting wall cooperating with a part of said insulation layer that covers said first mesa surface to form a second included angle that ranges from 105° to 165°.

7. The micro light-emitting device as claimed in claim 6, wherein said second included angle ranges from 120° to 150°.

8. The micro light-emitting device as claimed in claim 1, wherein said base frame includes a substrate and a bonding layer, said bonding layer being disposed on said substrate, said bridging structure being disposed on said bonding layer and connecting said bonding layer to said micro light-emitting diode.

9. The micro light-emitting device as claimed in claim 8, wherein said bonding layer is made of a benzocyclobutene (BCB) adhesive, silicone, a ultraviolet adhesive, or resin.

10. The micro light-emitting device as claimed in claim 1, wherein said bridging structure is made of a dielectric material, a metal material, or a semiconductor material.

11. The micro light-emitting device as claimed in claim 1, wherein said micro light-emitting diode has a flip-chip structure.

12. The micro light-emitting device as claimed in claim 1, wherein said base frame has an indented receiving space for disposing said micro light-emitting diode, and said micro light-emitting device includes a sacrificial layer, said sacrificial layer being disposed in said indented receiving space and between said micro light-emitting diode and said base frame.

13. The micro light-emitting device as claimed in claim 12, wherein a part of said sacrificial layer covering said connecting wall of said micro light-emitting diode has a thickness no smaller than 1 μm.

14. A micro light-emitting diode, comprising:
a semiconductor epitaxial structure including a first semiconductor layer, a second semiconductor layer, and an active layer disposed between said first semiconductor layer and said second semiconductor layer, said semiconductor epitaxial structure having a first mesa surface defined by said first semiconductor layer that is exposed from a recess of said semiconductor epitaxial structure, a second mesa surface defined by said second semiconductor layer, and a connecting wall disposed between and interconnecting said first mesa surface and said second mesa surface,
a first contact electrode disposed on said first mesa surface and electrically connected to said first semiconductor layer,
a second contact electrode disposed on said second mesa surface and electrically connected to said second semiconductor layer,
a first bonding electrode disposed on and electrically connected to said first contact electrode; and
a second bonding electrode disposed on and electrically connected to said second contact electrode,
wherein said connecting wall cooperates with said first mesa surface to form a first included angle, where 105°≤θ1≤165°.

15. The micro light-emitting diode as claimed in claim 14, wherein said first included angle ranges from 120° to 150°.

16. The micro light-emitting diode as claimed in claim 14, wherein said first bonding electrode extends onto said second mesa surface and is flush with said second bonding electrode.

17. The micro light-emitting diode as claimed in claim 14, further comprising an insulation layer that covers said connecting wall, said first mesa surface, and said second mesa surface, a part of said insulation layer that covers said connecting wall cooperating with a part of said insulation layer that covers said first mesa surface to form a second included angle that ranges from 105° to 165°.

18. The micro light-emitting diode as claimed in claim 17, wherein said second included angle ranges from 120° to 150°.

19. A method for manufacturing a micro light-emitting device, comprising steps of:
forming a semiconductor epitaxial structure on a growth substrate, the semiconductor epitaxial structure including a first semiconductor layer, a second semiconductor layer, and an active layer disposed between the first semiconductor layer and the second semiconductor layer;
removing a portion of the semiconductor epitaxial structure to expose the first semiconductor layer and to form a first mesa surface, a second mesa surface, and a connecting wall, the first mesa surface being defined by the exposed first semiconductor layer, the second mesa surface being defined by the second semiconductor layer, the connecting wall being disposed between and interconnecting the first mesa surface and the second mesa surface, and cooperating with the first mesa surface to form a first included angle, where 105°≤θ1≤165°;
forming a first contact electrode and a second contact electrode on the first mesa surface and the second mesa surface, respectively, and forming a first bonding electrode and a second bonding electrode on the first contact electrode and the second contact electrode, respectively, so as to obtain a micro light-emitting diode;
forming a sacrificial layer on the micro light-emitting diode;
providing a base frame having an indented receiving space;
bonding the micro light-emitting diode to the base frame with the sacrificial layer facing the base frame so that the micro light-emitting diode is disposed in the indented receiving space of the base frame;
removing the growth substrate; and
separating the micro light-emitting diode from the base frame by transfer printing and transferring the micro light-emitting diode onto a packaging substrate.

20. The method for manufacturing the micro light-emitting device as claimed in claim 19, wherein the first included angle ranges from 120° to 150°.
